(19) United States
(12) Patent Application Publication
(10) Pub. No.: US 2009/0197015 A1
(43) Pub. Date: Aug. 6, 2009

(54) METHOD AND APPARATUS FOR CONTROLLING PLASMA UNIFORMITY

(75) Inventors: Jozef Kudela, Sunnyvale, CA (US); Gaku Furuta, Sunnyvale, CA (US); Carl A. Sorensen, Morgan Hill, CA (US); Soo Young Choi, Fremont, CA (US); John M. White, Hayward, CA (US)

Correspondence Address: DUGAN & DUGAN, PC, 245 Saw Mill River Road, Suite 309, Hawthorne, NY, 10532, US

(73) Assignee: APPLIED MATERIALS, INC., Santa Clara, CA (US)

(21) Appl. No.: 12/344,210

(22) Filed: Dec. 24, 2008

Related U.S. Application Data
(60) Provisional application No. 61/016,593, filed on Dec. 25, 2007.
(60) Provisional application No. 61/016,594, filed on Dec. 25, 2007.

(51) Int. Cl. C23C 16/513

(52) U.S. Cl. 427/569; 118/723 R

(57) ABSTRACT

Systems, methods, and apparatus involve a plasma processing chamber for depositing a film on a substrate. The plasma processing chamber includes a lid assembly having a ground plate, a backing plate, and a non-uniformity existing between the ground plate and the backing plate. The non-uniformity may interfere with RF wave uniformity and cause an impedance imbalance between portions of the ground plate and backing plate. The non-uniformity may include a structure or a reduced spacing of non-uniform surfaces. A reduced spacing of non-uniform surfaces may exist where a first distance between the ground plate and the backing plate at a first end is different from a second distance between the ground plate and the backing plate at a second end. The structure may be from 2 cm to 10 cm thick, cover from 20% to 50% of the backing plate, and be located away from a discontinuity existing inside the chamber.

This application claims priority to U.S. Provisional Patent Application Ser. No. 61/016,593, filed on Dec. 25, 2007, titled “METHOD AND APPARATUS FOR CONTROLLING PLASMA UNIFORMITY BY PLACING CAPACITORS, INDUCTORS OR DIELECTRIC PLATES IN THE LID ASSEMBLY” (Attorney Docket 12627/L) and to U.S. Provisional Patent Application Ser. No. 61/016,594, filed on Dec. 25, 2007, titled “METHOD AND APPARATUS FOR CONTROLLING PLASMA UNIFORMITY BY VARIANCES IN DISTANCE AT DIFFERING POINTS BETWEEN A GROUND PLATE AND A BACKING PLATE” (Attorney Docket 12627/L2), each of which is hereby incorporated herein by reference in its entirety for all purposes.

### CROSS-REFERENCE TO RELATED APPLICATIONS

This application is related to U.S. Patent Application Publication No. 2008/0188033, to Choi et al., filed on Feb. 6, 2007, published Aug. 7, 2008, titled “MULTI-JUNCTION SOLAR CELLS AND METHODS AND APPARATUSES FOR FORMING THE SAME” (Attorney Docket 011709USA/P01) and incorporated by reference herein in its entirety for all purposes.

### FIELD OF THE INVENTION

The invention relates generally to plasma processing of materials. In particular, the invention relates to plasma processing chamber modifications to improve the film uniformity of large area substrates.

### BACKGROUND OF THE INVENTION

Many of the fabrication techniques developed for manufacturing integrated circuits on silicon wafers have been adapted to fabricating displays, thin film solar cells, and other circuits on large flat panels of glass and other materials. One such technique is plasma enhanced chemical vapor deposition (PECVD). The flat panel fabrication equipment has long been distinguished from wafer fabrication equipment by the size and the rectangular shape of the panels. Some of the earliest flat panels had sizes of about 500 mm on a side, but there has been a continuing trend toward larger panels. Some of the most recent panels are 2200 mm×2500 mm, and even larger panels are being contemplated.

### SUMMARY OF THE INVENTION

In an aspect of the invention, a modular system may comprise at least one modular plasma processing chamber and a non-uniformity. The modular plasma processing chamber may have a lid assembly including a ground plate and a backing plate, and the non-uniformity may be located between the ground plate and the backing plate, wherein the non-uniformity includes one of a structure and a reduced spacing. The structure may include at least one of a capacitor, an inductor and a dielectric plate.

In other aspects of the invention, a further modular system may comprise at least one modular plasma processing chamber, having a lid assembly having a ground plate, a backing plate, a first end, a second end, and a space between the ground plate and the backing plate, such that a first distance between the ground plate and the backing plate at the first end is different from a second distance between the ground plate and the backing plate at the second end.

In further aspects of the invention, an apparatus may comprise a plasma processing chamber for depositing a film on a substrate. The plasma processing chamber may have a center, an RF feed providing power at a frequency, a physical non-uniformity or structure causing interference with and affecting the RF feed emissions, and a substrate support assembly having an area greater than or about 2 m². The film may comprise silicon nitride or hydrogenated silicon nitride. Any suitable RF frequency may be used. The apparatus further may comprise a discontinuity inside the plasma processing chamber, such as a window or a slit valve. The interference with the RF emissions of the RF feed may be adjusted relative to the discontinuity.

Additional aspects of the invention may include another apparatus comprising a plasma processing chamber for depositing a film on a substrate, the plasma processing chamber having a lid assembly having a ground plate, a backing plate, and a structure positioned between the ground plate and the backing plate. The structure may be from 2 cm to 10 cm thick. The structure may include at least one of an inductor, a capacitor and a dielectric plate. The structure may cover from 20% to 50% of the backing plate. The structure may be located away from a discontinuity inside the chamber.

A further apparatus may comprise a plasma processing chamber having a lid assembly including a ground plate, a backing plate, a first end, a second end, and a space between the ground plate and the backing plate, such that a first distance between the ground plate and the backing plate at the first end is different from a second distance between the ground plate and the backing plate at the second end. The first distance may be shorter than the second distance by at least 20%. The first end may be located away from a discontinuity inside the plasma processing chamber.

In additional aspects of the invention, a method for processing a substrate in an apparatus may be performed, where the apparatus may comprise a plasma processing chamber for depositing a film on a substrate, the chamber having a lid assembly having a ground plate and a backing plate. The method comprises providing a non-uniformity positioned between the ground plate and the backing plate. The non-uniformity may include a structure positioned between the ground plate and the backing plate. The non-uniformity also may include a reduced spacing, such that the method comprises varying a first distance from a second distance, so that the first distance is shorter than the second distance. The first distance exists between the ground plate and the backing plate at a first end, and the second distance exists between the ground plate and the backing plate at a second end.

Other features and aspects of the present invention will become more fully apparent from the following detailed description of exemplary embodiments, the appended claims, and the accompanying drawings.

### BRIEF DESCRIPTION OF THE DRAWINGS

By reference to the appended drawings, which illustrate exemplary embodiments of the invention, the detailed description provided below explains in detail various features, advantages and objects of the present invention.

It is to be noted, however, that the appended drawings are not intended to necessarily be to scale or mechanically complete. They illustrate only isolated embodiments of this invention; they therefore are not to be considered as limiting of its scope, for the invention may admit to other equally effective embodiments.

FIG. 1 is a schematic of a planar view of one embodiment of a modular processing system with at least one plasma process apparatus in accordance with the present invention.

FIG. 2 is a schematic of a cross-sectional elevational view of one embodiment of a plasma deposition apparatus.

FIG. 3 is a schematic of a cross-sectional elevational view of another embodiment of a plasma deposition apparatus.

FIG. 4 is a schematic of a cross-sectional elevational view of a further embodiment of a plasma deposition apparatus.

### DETAILED DESCRIPTION

Flat panel displays (FPDS) are typically made by sandwiching liquid crystals between two glass substrates. One substrate is a color filter and the other substrate contains an array of thin film transistors (TFTs), and is therefore, referred to as the TFT array substrate. The thin films of the TFT array substrate are deposited using a plasma process. As the demand for larger and larger displays continues, the substrates' areas have been increased from 1 square meter to over 2 square meters, and the ability to make such large displays is challenged. The films may be deposited by PECVD. The challenge arises because it is difficult to create and sustain a uniform plasma density over such a large area. Without a uniform plasma density, film properties such as refractive index, wet etch rate, stress, atomic ratio, percentage of hydrogen bonding and thickness are also non-uniform across the panel (also referred to as a substrate). With non-uniform film properties or sub-standard film properties, performance capabilities of the TFT are directly impacted.

### TFTs and Films of Interest

Before discussing the plasma processing of films, a brief description of one form of TFT used in panels will be described. Generally speaking, TFTs are made by depositing alternating layers of conducting, insulating or semiconducting layers on a substrate. In an inverse staggered amorphous silicon (α-Si) TFT (also known as a back channel etch (BCE) inverted staggered (bottom gate) TFT structure), a semiconducting intrinsic well layer is deposited directly on the gate dielectric layer (an insulating layer). The intrinsic well is usually amorphous silicon (α-Si) and subsequent deposition is followed to form doped n-type or p-type semiconductor layer. The gate dielectric layer can be silicon dioxide or silicon nitride. This structure has the advantage that both the semiconducting silicon films and the insulating film can be deposited in a single PECVD pump-down run. Therefore, this structure is one of the more preferred TFTs. More layers are added to the structure for conductors, but ultimately, the TFT structure is capped with a passivating layer, typically of silicon nitride. The silicon nitride (SiNₓ) layers acting as gate dielectric or passivating layers are of particular interest in this invention. A more complete description of the inverse staggered TFT can be found in U.S. patent application Ser. No. 10/962,936 entitled “Method of Controlling the Uniformity of PECVD-Deposited Thin Films,” by Choi et al., filed Oct. 12, 2004, and incorporated herein by reference.

In lieu of using SiNₓ as a gate dielectric, hydrogenated silicon nitride (α-SiNₓ:H) PECVD thin films are said to be widely used as a gate dielectric for hydrogenated amorphous silicon (α-Si:H) TFT applications. SiNₓ films are characterized by a nitrogen-to-silicon ratio of about 1.33:1. Films of α-SiNₓ:H are characterized by a nitrogen-to-silicon ratio greater than or equal to 1.5:1. Such α-SiNₓ:H films are attractive due to the good interfacial property between an α-Si:H layer and an α-SiNₓ:H layer. However, the α-Si:H TFTs with α-SiNₓ:H gate dielectrics are reported to have instability problems, such as threshold voltage shift and the inverse sub-threshold slope under a DC gate voltage bias. These instability problems are said to be caused by the high trap density in the α-SiNₓ:H film and the defects created at the α-Si:H/α-SiNₓ:H interface. Charge trapping in the α-SiNₓ:H is said to be from the electron injection under an applied field and due to the localized states of the Si dangling bonds, Si—H and N—H bonds in the forbidden gap. Therefore, reduction of the hydrogen in the form of N—H and Si—H bonds in the α-SiNₓ:H film is desired.

SiNₓ or α-SiNₓ:H films deposited at lower temperatures (<300 C), as needed for plastic substrates, also have higher Si—H content. These high hydrogen content films (40%) require a higher threshold voltage than TFTs produced on glass at higher (>300 C) temperatures resulting in low ON current. It would be beneficial to lower the threshold voltage of TFTs produced at low temperatures. Low temperature deposition is also needed for passivation applications, because high temperatures cause degradation of TFT channel ion migration characteristics and damage source/drain metals.

Therefore, SiNₓ and α-SiNₓ:H films are needed that have low Si—H percentages and that can be PECVD deposited at normal and reduced (<300 C) temperatures as well as meeting typical requirements (e.g., stress, deposition rate, and uniformity). The aim is to achieve this goal by modifying the hardware of a PECVD chamber so as to provide a uniform plasma density in the PECVD chamber. Therefore, the next section begins the discussion of PECVD processing.

### Overview of PECVD Processing

Thin films for flat panel display and semiconductor substrates are typically processed using plasma enhanced chemical vapor deposition (PECVD). PECVD entails introducing a precursor gas or gas mixture into a vacuum chamber that contains a substrate. The precursor gas or gas mixture is typically directed downwardly through a distribution plate situated near the top of the chamber. The precursor gas or gas mixture in the chamber is energized (e.g., excited) into a plasma by applying radio frequency (RF) power to the chamber from one or more RF sources coupled to the chamber. The excited gas or gas mixture reacts to form a layer of material on a surface of the substrate that is positioned on a temperature-controlled substrate support assembly. Volatile by-products produced during the reaction are pumped from the chamber through an exhaust system.

As the sizes of substrates increase, maintaining uniform film thickness and film properties for large area plasma-enhanced chemical vapor deposition (PECVD) becomes an issue. The difference of deposition rate and/or film properties between the center and the edge of the substrate becomes significant due to non-uniform plasma density in the processing chamber.

### Plasma Density

In M. A. Lieberman's study of the source of the plasma density, he found that the standing wave effect (SWE), edge effects and skin effect are important factors for plasma density uniformity. Further details of Lieberman's findings can be found in M. A. Lieberman et al., “Standing wave and skin effects in large-area, high-frequency capacitive discharges,” Plasma Sources Sci. Technol., Vol. 11, pp. 283-292 (2002), and M. A. Lieberman, Principles of Plasma Discharges and Materials Processing, Wiley-Interscience, New York (1994).

For substrates less than 2 m² in area, edge effects and skin effects are not as crucial. Therefore, in these instances, the most important of Lieberman's factors is standing wave effect (SWE). Standing wave effects manifest themselves most clearly as a dome or increase in film thickness at the center of the substrate. SWEs become significant as substrate or electrode size approaches the RF wavelength (λₒ). A typical RF frequency used is 13.56 MHz, which corresponds to a wavelength of 22.11 m. For SWE to not be an issue, the following must hold true:

λₒ>>2.6(L/s)^{1/2}R

where L is the half spacing between electrodes, s is the plasma sheath thickness, and R is the radius (or in the case of a rectangular substrate, the half diagonal dimension of the substrate). Typical values for L and s are 20 mm and 1.5 mm, respectively. Therefore, for a panel 1100 mm×1250 mm, the right hand side of the equation is 5.6 m which is just at the limit of the comfort zone of being 4× smaller than the wavelength of approximately 22 m. Increasing the wavelength by lowering the RF frequency is undesirable because higher plasma potential (as indicated by peak-to-peak voltage) induces ion bombardment which may damage the substrate and films. For other reasons, such as, but not limited to, increasing the deposition rate, RF frequencies may be increased to as high as 30 MHz. Obviously, increased RF frequency will only exacerbate the standing wave effect. Therefore, if increased RF frequencies become a reality, robust solutions to the SWE problem and large substrate problems must be found.

Several attempts and some improvements are being made to address the SWE, and ultimately, the film properties. One strategy seeks to increase the width of the plasma sheath. Widening the sheath can be achieved, for example, by decreasing the spacing between the upper and lower electrodes in a parallel plate processing chamber. In general, narrower electrode spacing reduces the thick center feature of films. But no single electrode spacing is known to also yield acceptably-uniform film properties. Therefore, instead of changing the spacing of the electrodes, the shape of the diffuser may be changed to effectively yield simultaneous different electrode spacings at the edge of the chamber versus the center of the chamber. For example, if the diffuser is shaped so as to dome up in the center and push down at the edges, the effective electrode spacing would be wide in the center of the chamber and narrow at the chamber edges. If the electrode spacing is increased by widening it over the substrate, “overall” plasma density is reduced, insomuch as the electrical field between the two electrodes is decreased, and deposition thickness also is reduced, although SWE still exists. If the electrode spacing is decreased by narrowing it, “overall” plasma density is increased. Accordingly, by increasing electrode spacing in the middle and decreasing it at the corner, plasma uniformity over the plate can be compromised quite uniformly. More detail on the diffuser curvature method improving film uniformity can be found in U.S. patent application Ser. No. 11/173,210 entitled “Plasma Uniformity Control by Gas Diffuser Curvature,” to Choi et al., filed Jul. 1, 2005, and incorporated herein by reference.

Another strategy for tackling the SWE problem focuses on the gas distribution plates (aka gas diffuser plates) utilized to provide uniform process gas flow over the substrate. The diffuser plates have a plurality of holes through which the gas may travel. The density, arrangement, size, surface area and shape of the holes may be varied. For instance, the shapes of the holes in the diffuser plate can be cylindrical, flared, stepped, or one or more of a multitude of other variations. The shape of a hole is of interest because the hole actually acts as a small hollow cathode cavity to locally enhance ionization of the precursor gas or gas mixture. Local plasma density is believed to be an important factor in maintaining uniform film thickness and film properties across the large area substrates. The technique of varying the gas hole (or hollow cathode) shape is called the hollow cathode gradient (HCG) method and is described in more detail in previously referenced U.S. patent application Ser. No. 10/889,683, to Choi, et al., entitled “PLASMA UNIFORMITY CONTROL BY GAS DIFFUSER HOLE DESIGN,” filed Jul. 12, 2004, and incorporated herein by reference.

To counteract the skin effect mentioned by Lieberman, multiple grounding paths and grounding paths asymmetric both in location and conductance are connected to the susceptor (also known as the substrate support assembly). Details can be found in U.S. patent application entitled “ASYMMETRIC GROUNDING OF SUSCEPTOR,” by Furuta et al., incorporated herein by reference.

It also may be possible to tune other process parameters, such as pressure and gas flow ratios, in order to achieve acceptable thickness and properties uniformities.

The SWE concerns that started with substrate sizes greater than 1 m² may be ameliorated to some extent by some of the solutions previously discussed; however, for substrate sizes greater than 2 m², film and plasma uniformity problems persist despite implementing these proposed solutions.

### Slit Valve Effect and Film Properties

The greatest disruption in plasma uniformity for large area substrates may be the slit valve effect. For the purpose of this invention, large area substrates will be defined as substrates greater than or about 2 m². A PECVD chamber is generally symmetric, but it does have a slit valve on one end, through which the substrate enters and exits the chamber. Experience has shown that films are thicker and film properties are different near the slit valve. These phenomena are particularly relevant to the deposition of SiNₓ and α-SiNₓ:H films, which may be used for gate dielectric layers or passivation layers as part of the manufacture of electronic devices.

Table X summarizes a comparison of SiNₓ films deposited on two substrates, illustrating the trade-off between film uniformity and film quality for a 2200 mm×1870 mm substrate. The film stress, the Si—H content, and the thickness non-uniformity of distinct substrates A and B are compared. Film stress measurement units are expressed in E⁹ dynes/cm². Negative values of stress indicate a compressive film, whereas positive values indicate tensile. A compressive film is desired. In particular, a highly compressive film, yielding large negative values (−5 or higher, for example), is desired.

The Si—H content is measured by Fourier Transform Infrared (FTIR) spectroscopy. Low Si—H content is desired. Just how low depends upon the function of the film. For example, gate dielectrics or interface applications with α-Si may require Si—H content less than about 5%, preferably less than or equal to about 2%. Non-interface applications, such as passivation films, may use films with less than about 10% Si—H content, preferably less than about 8% Si—H. Substrates A and B were processed in the same PECVD chamber at approximately the same deposition rate, but process parameters were varied for each substrate in order to deposit a slightly different film on each. Substrate A values demonstrate that, for a substrate of this size, a relatively uniform film, i.e. non-uniformity of 8.4%, may be deposited, but the Si—H concentration and compressive film stress values are relatively poor. Conversely, substrate B values demonstrate that a low Si—H, high compressive stress film can be deposited at the cost of a poor thickness non-uniformity, i.e., 31%.

In addition, Table X, in particular by values for substrate B, also illustrates the slit valve effect. For each substrate, the film properties were measured at three locations: (1) at the edge of the substrate near the chamber window; (2) in the center of the substrate (and center of the chamber); and (3) near the edge of the substrate near the slit valve of the chamber (opposite the window). Referring to substrate B values, all of the film properties change as measured from one end of the substrate (near the window) to the other end of the substrate (near the slit valve). The deposition rate increases, the stress level doubles, and the Si—H content decreases.

TABLE X
Table X: Comparison of film properties and non-uniformity of
SiNₓ films on distinct substrates A and B.

| | | | | Location | |
|---|---|---|---|---|---|
| | | Location | Location | Slit | Non- |
| | | Window | Center | Valve | Uniformity |
| Substrate | Film | 0.9 | −0.3 | −1.1 | 8.4% |
| A | Stress | | | | |
| | % Si—H | 13.3 | 11.3 | 11.7 | |
| | Film | 6243 | 6560 | 6649 | |
| | Thickness | | | | |
| Substrate | Film | −3.0 | −5.8 | −6.7 | 31.3% |
| B | Stress | | | | |
| | % Si—H | 3.3 | 1.6 | 1.8 | |
| | Film | 5901 | 7230 | 7779 | |
| | Thickness | | | | |

The slit valve effect may be due to an ion coupling effect between the plasma and the open cavity area around the slit valve. The cavity creates a relatively longer RF ground return path, which in turn creates parasitic inductance of the plasma, resulting in denser plasma toward the slit valve side compared to plasmas near sides that do not have a cavity. This scenario is particularly true of for the deposition of SiNₓ and α-SiNₓ:H films, which may be used for gate dielectric layers or passivation layers as part of the manufacture of electronic devices. If another feature of the chamber, such as the window, had a similar cavity or discontinuity, then a similar effect would be expected to occur. Therefore, even though the effect is being referred to as the “slit valve effect,” another feature or discontinuity in a chamber also might induce the same problem of film non-uniformity, both in thickness and properties to be exhibited.

These major discontinuities in the chamber interior, such as the slit valve or possibly a window, within an otherwise essentially symmetric chamber, appear to be causing local plasma density distortions. Therefore, in order to reduce the distortions, the plasma density uniformity may be sought by (1) adjusting the RF feeding distribution, (2) inserting a structure, such as a dielectric plate, inductor, or capacitor, (described below in an explanation of a PECVD system and chamber), or (3) changing the spacing of ground plates and RF hot plates in the lid assembly. An operator also may combine each of the techniques (i.e., RF feeding point adjustment, structure use, and plate spacing adjustment) with one or more of the techniques discussed in the “Plasma Density” section (e.g., ground path modification, diffuser modification, etc.).

### Exemplary Systems

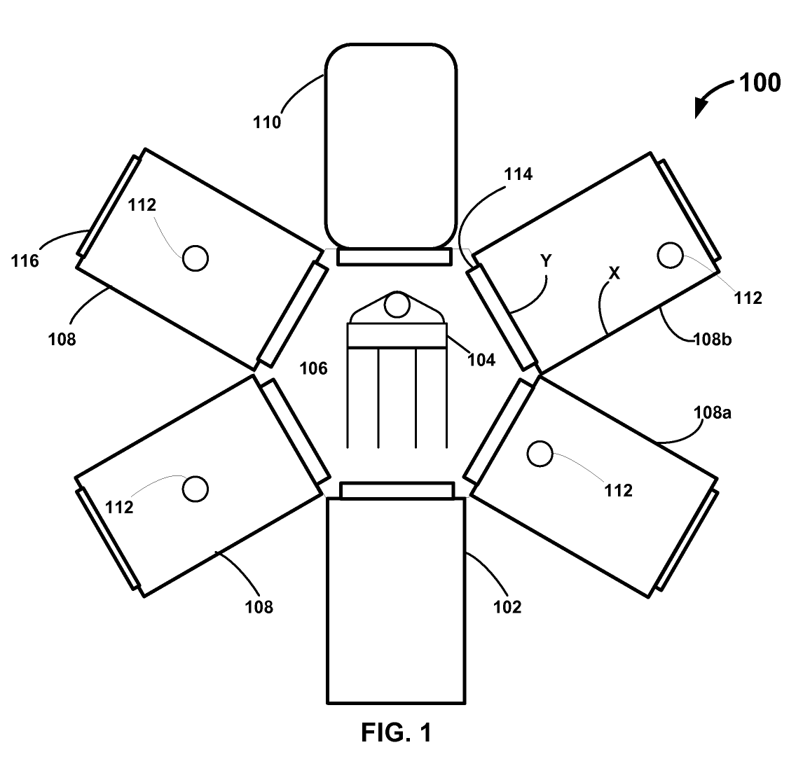

Referring to FIG. 1, a schematic depicts a planar view of an exemplary embodiment of a modular processing system 100 with at least one plasma process apparatus, in accordance with the present invention. The system 100 generally includes a loadlock chamber 102 for loading substrates (not shown) into the system 100; a robot assembly 104 in a transfer chamber 106 for transferring substrates; multiple processing chambers 108; and an optional heater 110. The processing chambers 108 include, among other features, a Radio Frequency (RF) feed 112, a slit valve 114 for communication of substrates from chamber the chamber, and a window, or viewport, 116 for observing movement of the substrate and the plasma discharge.

The number and types of processing chambers 108 can be varied. In the configuration shown in FIG. 1, two process chambers 108 have the RF feed 112 in the center of the chamber 108. Two of the other processing chambers 108a and 108b have the RF feed 112 in an asymmetric, or off-centered, location. Chamber 108a has the RF feed 112 near the slit valve 114. Chamber 108b has the RF feed 112 away from the slit valve 114. If coordinates are made on the chamber 108 with the long side of the chamber 108 being the x-axis and the short side the y-axis, the RF feed 112 in chamber 108a can be said displaced in the x direction, but not in the y direction. In contrast, RF feed 112 in chamber 108b is displaced in both the x and y directions.

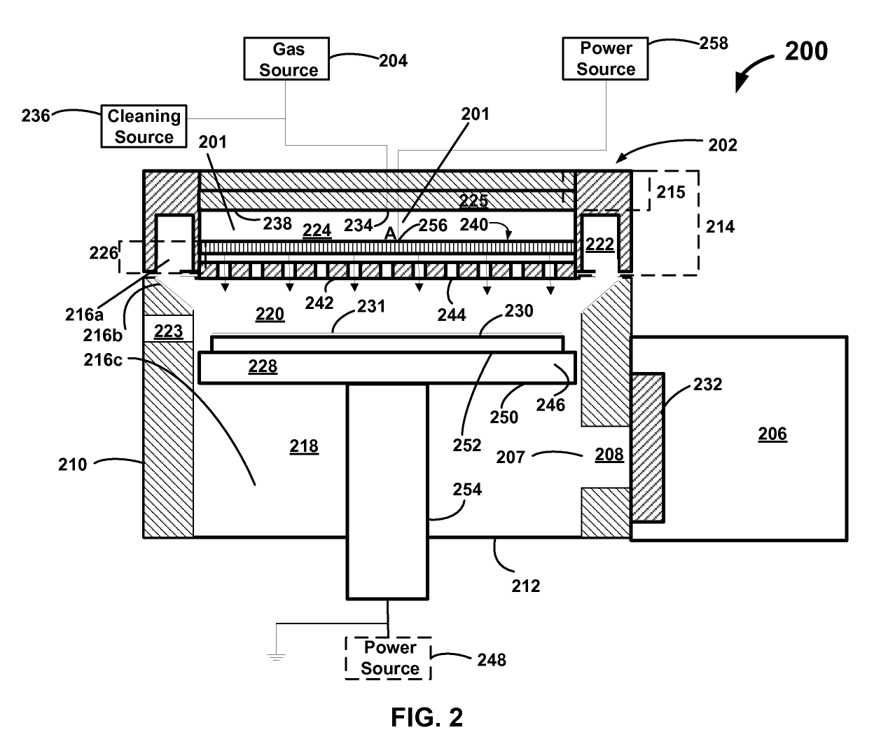

Referring to FIG. 2, a schematic illustrates a cross-sectional elevational view of an exemplary embodiment of a plasma enhanced chemical vapor deposition apparatus 200, in which the present invention may be implemented. PECVD apparatus 200 resembles those available from AKT, a division of Applied Materials, Inc., Santa Clara, Calif. The PECVD apparatus 200 generally includes at least one non-uniformity 201 in at least one processing chamber 202 coupled to a gas source 204 and a transfer chamber 206. Typically, processing chamber 202 is directly attached to transfer chamber 206 and may be in fluid communication with transfer chamber 206 via slit valve opening 208.

In accordance with aspects of the present invention, a first half of a RF hot back plate that is closer to a discontinuity, such as a slit valve, may be coupled to a grounded lid through an impedance lower than that of a second half of the back plate. A non-uniformity 201 present between a backing plate and a ground plate may interfere with the RF wave, such as RF wave uniformity, and cause an impedance imbalance that results in the coupling. In some embodiments, the non-uniformity 201 may include a structure, such as a dielectric material, may affect the impedance on one side. In other embodiments, the non-uniformity 201 may include a reduced spacing between a backing plate and a ground plate may affect the impedance on one side. In further embodiments, the non-uniformity 201 may include a modification of an RF feed, such as its placement.

The processing chamber 202 has walls 210, a chamber floor 212, and a lid assembly 214 that substantially define areas of a vacuum region 216A, 216B, 216C. The vacuum region 216A, 216B, 216C includes a lower chamber 218, a processing cavity 220, a pumping plenum 222, and a process gas plenum 224. The lid assembly 214 may include a cooling plate (not shown), a ground plate 225, or other plates. Processing cavity 220 is defined by gas distribution plate assembly 226, substrate support assembly 228, and pumping plenum 222. Processing cavity 220 is typically accessed through a slit valve opening 208 in the walls 210 which allows movement of a substrate 230 into and out of the processing chamber 202 from transfer chamber 206. A film 231 may be deposited on substrate 230. Typically a slit valve door 232 is used to isolate processing chamber 202 from the environment outside slit valve opening 208 with a vacuum-tight seal.

The walls 210 and chamber floor 212 may be fabricated from a unitary block of aluminum or other material compatible with processing. The walls 210 support lid assembly 214. Lid assembly 214 contains pumping plenum 222, which couples the processing cavity 220 to an exhaust port (not shown) for removing process gases and processing byproducts from processing cavity 220. Alternatively, an exhaust port may be located in chamber floor 212 of processing chamber 202, in which case pumping plenum 222 is not required for processing cavity 220. The wall 210 may also have a window 223 or view port for watching the substrate transfer or plasma discharge. Typically the window 223 is on the opposite side of the chamber 202 from the slit valve opening 208.

The lid assembly 214 typically is generally composed of two portions, an upper portion 215 and a lower portion. The upper portion 215 of the lid assembly 214 may include a variety of plates (not shown). One plate may be a cooling plate through which water travels to cool the apparatus. Another plate may be a grounding plate. The upper portion 215 of the lid assembly 214 also includes an entry port 234 through which process gases provided by the gas source 204 are introduced into the processing chamber 202. The entry port 234 is also coupled to a cleaning source 236. The cleaning source 236 typically provides a cleaning agent, such as dissociated fluorine, that is introduced into the processing chamber 202 to remove deposition by-products and films from processing chamber hardware, including the gas distribution plate assembly 226.

The gas distribution plate assembly 226 may be considered the lower portion of the lid assembly 214. The plate assembly 226 may be coupled to an interior side 238 of the upper portion 215 of the lid assembly 214. The shape of gas distribution plate assembly 226 typically conforms substantially to the perimeter of the glass substrate 230; for example, the shape may be polygonal for large area flat panel substrates or circular for wafers. The gas distribution plate assembly 226 includes a backing plate 240 with an orifice through which process and other gases supplied from the gas source 204 eventually are delivered to the processing cavity 220. The gas distribution plate assembly 226 typically includes a diffuser plate 242 (also known as a distribution plate or showerhead), suspended from a hanger plate (not shown). The diffuser plate 242 and hanger plate alternatively may comprise a single unitary member.

A plurality of gas passages 244 traverse the diffuser plate 242 to allow a predetermined distribution of gas to pass through the gas distribution plate assembly 226 and into the processing cavity 220. The diffuser plate 242 and backing plate 240 are RF hot. Gas distribution plates 226, which may be adapted to benefit from the invention, are described in commonly assigned U.S. patent application Ser. No. 09/922,219, filed Aug. 8, 2001, by Keller et al.; U.S. patent application Ser. No. 10/140,324, filed May 6, 2002, by Yim et al.; U.S. patent application Ser. No. 10/337,483, filed Jan. 7, 2003, by Blonigan et al.; U.S. Pat. No. 6,477,980, issued Nov. 12, 2002, to White et al.; U.S. patent application Ser. No. 10/417,592, filed Apr. 16, 2003, by Choi et al.; and U.S. patent application Ser. No. 10/823,347, filed on Apr. 12, 2004, by Choi et al.; each of which is hereby incorporated by reference in its entirety.

Substrate support assembly 228 may be temperature controlled and is centrally disposed within the processing chamber 202. The substrate support assembly 228 supports a glass substrate 230 during processing. In one embodiment, the substrate support assembly 228 comprises an aluminum body 246 that encapsulates at least one embedded heater (not shown). The heater, such as a resistive element, disposed in the substrate support assembly 228. The heater is depicted as being coupled to an optional power source 248, and the heater controllably heats the substrate support assembly 228 and the glass substrate 230 positioned thereon to a predetermined temperature. Typically, in a CVD process, the heater maintains the glass substrate 230 at a uniform temperature between about 150° C. to at least about 460° C., depending on the deposition processing parameters for the material being deposited.

The substrate support assembly's shape and dimensions generally correspond to those of the substrate. For the case of TFT panels, the substrates and the support assembly are rectangular, possibly with the support assembly being slightly larger. As is the case with all rectangles, the substrate support assembly 228 and the substrate 230 have a diagonal dimension that spans opposite corners. The diagonal and the half diagonal are values often used to describe the size of substrates. For example, an 1100 mm×1250 mm substrate has a half diagonal of 833 mm, i.e., 0.83 m. Likewise, the half diagonals for 1500 mm×1850 mm and 1870 mm×2200 mm substrates are 1.19 m and 1.44 m respectively.

Generally, the substrate support assembly 228 has a lower side 250 and an upper side 252. The upper side 252 supports the glass substrate 230. The lower side 250 has a stem 254 coupled thereto. The stem 254 couples the substrate support assembly 228 to a lift system (not shown) that moves the substrate support assembly 228 between an elevated processing position (as shown) and a lowered position, which facilitates substrate transfer to and from the processing chamber 202. The stem 254 additionally provides a conduit for electrical and thermocouple leads between the substrate support assembly 228 and other components of the PECVD system 200.

A bellows (not shown) is coupled between substrate support assembly 228 (or the stem 254) and the chamber floor 212 of the processing chamber 202. The bellows provides a vacuum seal between the processing cavity 220 and the atmosphere outside the processing chamber 202, while facilitating vertical movement of the support assembly 228. As introduced above, exemplary systems may be either bottom vacuum pumping via a bottom vacuum pumping port, or top vacuum pumping via a top vacuum pumping port.

The substrate support assembly 228 generally is grounded electrically such that radio frequency (RF) power feed 256 supplied by a power source 258 to gas distribution plate assembly 226, or other electrode positioned within or near the lid assembly 214 of the chamber 202, may excite gases present in the processing cavity 220, i.e., between the substrate support assembly 228 and the distribution plate assembly 226. Any suitable RF frequency may be used. For instance, some solar applications may use VHF-range frequencies, whereas some display applications may use 13.56 MHz. Exemplary frequency ranges may be from 13 MHz to 14 MHz, such as 13.56 MHz; from 14 MHz to 20 MHz; greater than or equal to 20 MHz; or greater than or equal to 30 MHz. The RF power feed 256 historically is located at or near the center of the chamber 202, as indicated by “A” in FIG. 2. However, the present invention is not limited to such a configuration and may locate the RF power feed 256 elsewhere.

For purposes of identifying position A, for example, let the long side of a rectangular substrate 230 (i.e., going from the window 223 to the slit valve opening 208) be the x-axis. Let the short side of the rectangular substrate 230 be the y-axis, and the center of the rectangular substrate 230 defines (x,y) coordinates (0,0). Using this coordinate system, the four corners of the rectangle define coordinates (−100%, −100%), (−100%, 100%), (100%, 100%) and (100%, −100%), where 100% represents half the length of a given axis.

The location of the RF feed 256 relative to center may depend upon the size of the substrate 230, process conditions (e.g., frequency, substrate support assembly temperature, power, pressure, gas flows, magnetic field, etc.), and hardware conditions (e.g., grounding configurations, diffuser configurations, materials coating the hardware, etc.). The RF power from power source 258 is generally selected commensurate with the size of the substrate 230 to drive the chemical vapor deposition process. Larger substrates 230 require higher magnitude RF power for PECVD processing, resulting in larger currents, including higher voltage current flowing to the gas distribution plate assembly 226 and lower voltage current flowing from the processing cavity 220 back to ground or neutral in order to complete the electrical circuit of the plasma generation.

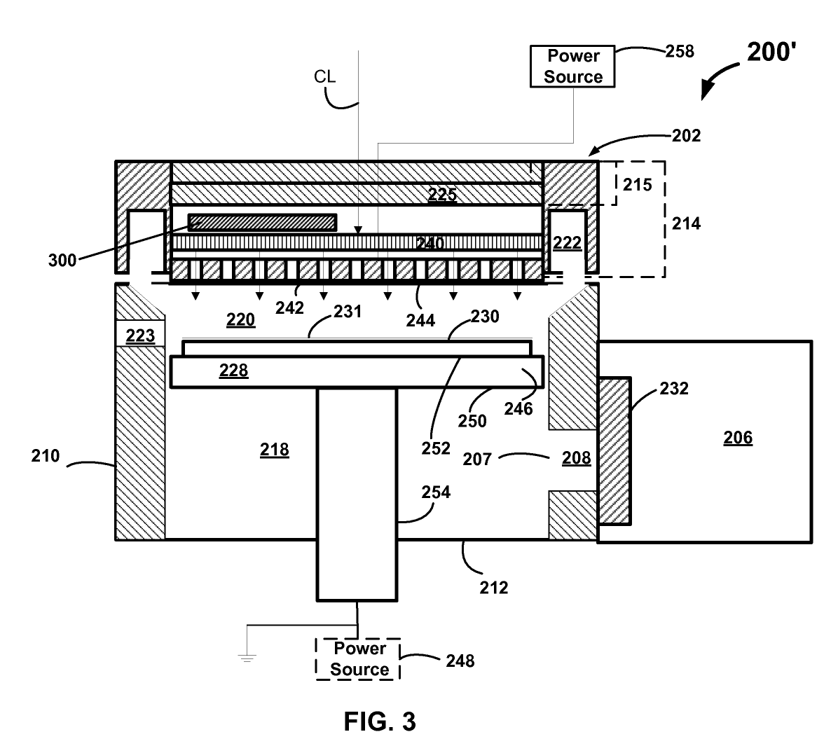

Referring to FIG. 3, another exemplary embodiment of the preset invention is depicted involving a plasma enhanced chemical vapor deposition apparatus 200′. In FIG. 3, in order to alter the plasma distribution and ultimately the film properties, a structure 300 may be placed between the backing plate 240 and the upper portion 215 of the lid assembly 214. The structure 300 may be an inductor, a capacitor or piece of dielectric material. Suitable dielectric materials include, for instance, glass or ceramics, such as aluminum oxide. Moreover, the structure 300 need not be a dielectric; instead, the structure 300 may include a semiconductor or conductor material, with appropriate modifications made to account for the possible field effects generated by the non-dielectric material. The structure 300 may be placed on the backing plate 240. The structure 300 may be one piece or several pieces placed next to each other. Depending on the circumstances, a primary purpose of the structure 300 may be to slow down the RF wave. The structure 300 may interfere with the emissions of the RF feed to slow down the RF wave.

Generally speaking, the structure 300 may cover from about 20% to 50% of the area of the backing plate 240 or the substrate 230, preferably from 20% to 30%. For example, if a substrate 230 is 1700 mm×2000 mm then a structure 300 on the order of 795 mm×1030 mm may be used. The structure thickness preferably may be from 2 mm to 10 mm. Generally, the structure 300 will be rectangular, but it is also possible to have other shapes to customize for chamber discontinuities. Similarly, the thickness of the dielectric structure 300 does not have to be uniform, but may be tapered in response to chamber discontinuities.

The placement of the structure(s) 300 depends on the location(s) of the one or more discontinuities causing the most plasma non-uniformity issues. Therefore, in the case where the slit valve 208 is causing non-uniform plasma (e.g., more dense plasma close to the slit valve 208) a structure 300 may be placed opposite the slit valve 208, as shown in FIG. 3. Also as shown in FIG. 3, for a substrate 230 of a given size of 1700 mm×2000 mm, the structure 300 may be placed 0 cm to 25 cm from the edge of the backing plate 240, preferably from 2 cm to 15 cm. The structure 300 preferably may be placed from 0 cm to 45 cm from a center line A of the backing plate 240, or from 0% to as much as 35% of the longer side of the backing plate 240 away from a center line CL of a backing plate 240. If the backing plate 240 is circular, structure 300 may be placed from 0% to as much as 35% of the diameter of the backing plate 240 away from the center line CL of the backing plate 240.

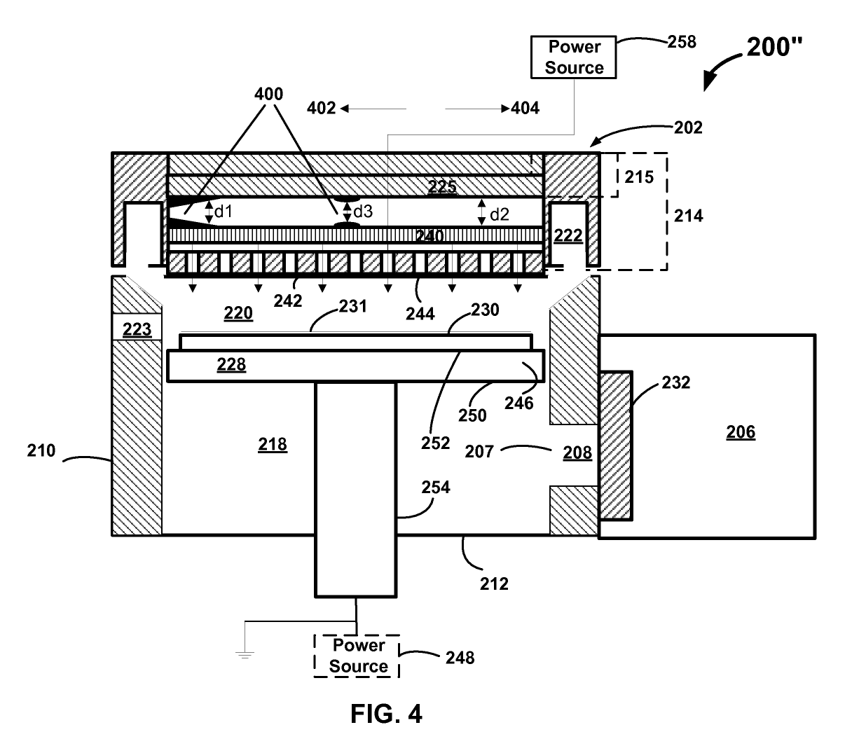

Referring to FIG. 4, in a further exemplary embodiment of a plasma enhanced chemical vapor deposition apparatus 200″, the process gas plenum 224, which is a space between the backing plate 240 and ground plate 225, may be altered to be non-uniform to include a reduced spacing 400. Typically, the plates 225 and 240 are parallel, defining a uniform space as the process gas plenum 224. However, if the plasma density is non-uniform due to a discontinuity 207 (the slit valve cavity 208, for example) in the chamber 202, then varying the spacing between points on the ground plate 225 and RF hot backing plate 240 may change the inductance, and hence the plasma density and film properties. Therefore, referring to FIG. 4, if the distance d1 on a first end 402 of the chamber 202 opposite a discontinuity 207 at a second end 404 is decreased relative to a distance d2 near the discontinuity 207 in the chamber 202, the plasma density may be altered. The distance d1 may be decreased by about 20% to 80% of the distance d2 on the discontinuity side. Such variances in distances between ground plate 225 and backing plate 240 may be accomplished by numerous configurations, including having the ground plate 225, the backing plate 240, or both, having an uneven (e.g., wavy) surface, such as depicted at distance d3.

Examples of additional embodiments in accordance with the present invention would include the following:

A modular system may comprise at least one modular plasma processing chamber and a structure. The modular plasma processing chamber may have a lid assembly including a ground plate and a backing plate, and the structure may be located between the ground plate and the backing plate, wherein the structure includes at least one of a capacitor, an inductor and a dielectric plate.

A further modular system may comprise at least one modular plasma processing chamber, having a lid assembly having a ground plate, a backing plate, a first end, a second end, and a space between the ground plate and the backing plate, such that a first distance between the ground plate and the backing plate at the first end is different from a second distance between the ground plate and the backing plate at the second end.

An apparatus may comprise a plasma processing chamber for depositing a film on a substrate. The plasma processing chamber may have a center, an RF feed providing power at a frequency, a physical non-uniformity or structure causing interference with and affecting the RF feed emissions, and a substrate support assembly having an area greater than or about 2 m². The film may comprise silicon nitride or hydrogenated silicon nitride. Any suitable RF frequency may be used. For instance, some solar applications may use VHF-range frequencies, whereas some display applications may use 13.56 MHz. Exemplary frequency ranges may be from 13 MHz to 14 MHz, such as 13.56 MHz; from 14 MHz to 20 MHz; greater than or equal to 20 MHz; or greater than or equal to 30 MHz. The apparatus further may comprise a discontinuity inside the plasma processing chamber, such as a window or a slit valve. The interference with the RF emissions of the RF feed may be adjusted relative to the discontinuity.

Another apparatus may comprise a plasma processing chamber for depositing a film on a substrate, the plasma processing chamber having a lid assembly having a ground plate, a backing plate, and a structure positioned between the ground plate and the backing plate. The film may comprise silicon nitride or hydrogenated silicon nitride. The structure may be from 2 cm to 10 cm thick. The structure may include at least one of an inductor, a capacitor and a dielectric plate. Such a dielectric plate may comprise glass or ceramic. Such a ceramic may comprise aluminum oxide. The structure may cover from 20% to 50% of the backing plate. The apparatus may further comprise a discontinuity inside the chamber. The structure may be located away from the discontinuity. For instance, the discontinuity may comprise a window or a slit valve.

A further apparatus may comprise a plasma processing chamber having a lid assembly including a ground plate, a backing plate, a first end, a second end, and a space between the ground plate and the backing plate, such that a first distance between the ground plate and the backing plate at the first end is different from a second distance between the ground plate and the backing plate at the second end. The film may comprise silicon nitride or hydrogenated silicon nitride. The first distance may be shorter than the second distance by at least 20%. A discontinuity may exist inside the plasma processing chamber, and the discontinuity may be located away from the first end. The discontinuity may comprise a slit valve or a window.

Another apparatus comprising a plasma processing chamber for depositing a film on a substrate may include a substrate support assembly, a center, an end, a slit valve at the end, a lid assembly, a ground plate and a backing plate. The lid assembly may have a dielectric plate between the ground plate and the backing plate, and the substrate support assembly may have an area greater than or equal to about 2 square meters. The dielectric plate may be offset from 20 cm to 40 cm from the center of the plasma processing chamber in a direction away from the slit valve, and the dielectric plate may cover from 20% to 50% of the backing plate. The film may include at least one of a silicon nitride film and a hydrogenated silicon nitride film.

A further apparatus comprising a plasma processing chamber for depositing a film on a substrate may include a substrate support assembly, a first end, a second end, a slit valve at the second end, a lid assembly, a ground plate and a backing plate, wherein a space exists between the ground plate and the backing plate. The substrate support assembly may have an area greater than or equal to 2 square meters. A first distance between the ground plate and the backing plate at the first end may be shorter by at least 20% than a second distance between the ground plate and the backing plate at the second end. The film may include at least one of a silicon nitride film and a hydrogenated silicon nitride film.

A method for processing a substrate in an apparatus may be performed, where the apparatus may comprise a plasma processing chamber for depositing a film on a substrate, the chamber having a lid assembly having a ground plate and a backing plate. The method comprises providing a non-uniformity positioned between the ground plate and the backing plate. The non-uniformity may include a structure positioned between the ground plate and the backing plate.

A further method for processing a substrate in an apparatus may be performed, where the apparatus may comprise a plasma processing chamber for depositing a film on a substrate, the chamber having a lid assembly having a ground plate, a backing plate, a first end, a second end, and a space between the ground plate and the backing plate. A first distance exists between the ground plate and the backing plate at the first end, and a second distance exists between the ground plate and the backing plate at the second end. The method comprises varying the first distance from the second distance, such that the first distance is shorter than the second distance.

These methods further may comprise maintaining a process temperature set point. The process temperature set point may be less than or equal to 300 C. Alternatively, the process temperature set point may be greater than 300 C.

A film comprising silicon and nitrogen may be deposited in an apparatus comprising a plasma processing chamber for depositing the film on a substrate. In a first version, the plasma processing chamber may have a center, an RF feed experiencing interference from a structure in the chamber, and a substrate support assembly having an area greater than or about 2 m². In a second version, the plasma processing chamber may have a lid assembly having a ground plate, a backing plate, and a structure positioned between the ground plate and the backing plate. In a third version, the plasma processing chamber may have a lid assembly including a ground plate, a backing plate, a first end, a second end, and a space between the ground plate and the backing plate, such that a first distance between the ground plate and the backing plate at the first end is different from a second distance between the ground plate and the backing plate at the second end.

In each case, the film may have a ratio of nitrogen to silicon of about 1.33:1. The film alternatively may have a ratio of nitrogen to silicon of at least 1.5:1. The film further may comprise hydrogen, wherein a percentage of Si—H bonds may be less than 10%. The percentage of Si—H bonds alternatively may be less than 5%. The film may have a film stress greater than −1E⁹ dynes/cm² in some circumstances, or greater than −6E⁹ dynes/cm² in other circumstances, or greater than −10E⁹ dynes/cm² in still other circumstances. In this context, greater stress refers to a larger negative number, indicating higher compressive stress.

Accordingly, while the present invention has been disclosed in connection with exemplary embodiments thereof, it should be understood that other embodiments may fall within the spirit and scope of the invention, as defined by the following claims.

What is claimed is:

1. A modular system comprising:
at least one modular plasma processing chamber, having a lid assembly including a ground plate and a backing plate; and
a non-uniformity located between the ground plate and the backing plate;
wherein the non-uniformity includes at least one of a structure and a reduced spacing between the ground plate and the backing plate, and
wherein the reduced spacing exists when a first distance between the ground plate and the backing plate at a first end is different from a second distance between the ground plate and the backing plate at a second end.

2. An apparatus comprising:
a plasma processing chamber for depositing a film on a substrate;
wherein the plasma processing chamber has a lid assembly having a ground plate, a backing plate, and a non-uniformity positioned between the ground plate and the backing plate.

3. The apparatus of claim 2, wherein the film comprises silicon nitride.

4. The apparatus of claim 2, wherein the film comprises hydrogenated silicon nitride.

5. The apparatus of claim 2, wherein the non-uniformity comprises a structure.

6. The apparatus of claim 5, wherein the structure is from 2 cm to 10 cm thick.

7. The apparatus of claim 5, wherein the structure includes at least one of an inductor, a capacitor and a dielectric plate.

8. The apparatus of claim 7, wherein the dielectric plate comprises glass or ceramic.

9. The apparatus of claim 5, wherein the structure comprises a non-dielectric material.

10. The apparatus of claim 5, wherein the structure covers from 20% to 50% of the backing plate.

11. The apparatus of claim 2, further comprising a discontinuity inside the chamber.

12. The apparatus of claim 11, wherein the structure is located away from the discontinuity.

13. The apparatus of claim 11, wherein said discontinuity comprises a window.

14. The apparatus of claim 11, wherein said discontinuity comprises a slit valve.

15. The apparatus of claim 2, wherein the non-uniformity comprises a reduced spacing;
wherein the plasma processing chamber has a first end, a second end, and a space between the ground plate and the backing plate; and
wherein the reduced spacing exists when a first distance between the ground plate and the backing plate at the first end is different from a second distance between the ground plate and the backing plate at the second end.

16. The apparatus of claim 15, wherein the first distance is shorter than the second distance by at least 20%.

17. The apparatus of claim 2, wherein said plasma processing chamber has a substrate support assembly, a center, a first end, a second end, and a slit valve at the second end;
wherein a space exists between the ground plate and the backing plate;
wherein the substrate support assembly has an area greater than or equal to about 2 square meters;
wherein said non-uniformity comprises a reduced spacing or a dielectric plate;
wherein the reduced spacing exists when a first distance between the ground plate and the backing plate at the first end is shorter by at least 20% than a second distance between the ground plate and the backing plate at the second end;
wherein the dielectric plate is offset from 20 cm to 40 cm from the center of the plasma processing chamber in a direction away from the slit valve;
wherein said dielectric plate covers from 20% to 50% of the backing plate; and
wherein said film includes at least one of a silicon nitride film and a hydrogenated silicon nitride film.

18. A method for processing a substrate in an apparatus comprising:
a plasma processing chamber for depositing a film on a substrate;
wherein the plasma processing chamber has a lid assembly having a ground plate and a backing plate;
the method comprising providing a non-uniformity positioned between the ground plate and the backing plate.

19. The method of claim 18, wherein the non-uniformity comprises a structure.

20. The method of claim 19, wherein the structure includes at least one of an inductor, a capacitor and a dielectric plate.

21. The method of claim 19, wherein the structure comprises a non-dielectric material.

22. The method of claim 18, further comprising maintaining a process temperature set point less than or equal to 300 C.

23. The method of claim 18, further comprising maintaining a process temperature set point greater than 300 C.

24. The method of claim 18, wherein the non-uniformity comprises a reduced spacing;
wherein the plasma processing chamber has a first end, a second end, and a space between the ground plate and the backing plate; and
wherein the reduced spacing exists when a first distance between the ground plate and the backing plate at the first end is different from a second distance between the ground plate and the backing plate at the second end.

25. The method of claim 24, wherein the first distance is shorter than the second distance by at least 20%.
